(19) United States
(12) Patent Application Publication
(10) Pub. No.: US 2025/0028895 A1
(43) Pub. Date: Jan. 23, 2025

(54) AUTOMATED CELL BLACK BOXING FOR LAYOUT VERSUS SCHEMATIC

(71) Applicant: Siemens Industry Software Inc., Plano, TX (US)

(72) Inventor: Kesmat Shahin, Nasr City, Cairo (EG)

(73) Assignee: Siemens Industry Software Inc., Plano, FL (US)

(21) Appl. No.: 18/703,790

(22) PCT Filed: Nov. 3, 2021
(86) PCT No.: PCT/US2021/057800

§ 371 Date: Apr. 23, 2024

(51) Int. Cl. G06F 30/398; G06F 30/392

(52) U.S. Cl. CPC G06F 30/398; G06F 30/392

(57) ABSTRACT

Text containers comprising information of cell ports are determined based on statements for cell ports in a rule file. Drawn layers comprising cell ports are determined based on the determined text containers or based on statements for attaching each of the test containers to a layout design layer in the rule file. Layout design layers connected to the drawn layers comprising cell ports are determined based on statements for connecting layout design layers in the rule file. A file for cell port detection is generated which associates each of the text containers comprising information of cell ports with one or more of the drawn layers comprising cell ports and one or more of the layout design layers connected to the one or more of the drawn layers comprising cell ports. The file for cell port detection can be used for extracting ports for cells to be black boxed.

### FIELD OF THE DISCLOSED TECHNOLOGY

The present disclosed technology relates to the field of circuit design and manufacture. Various implementations of the disclosed technology may be particularly useful for layout extraction and verification.

### BACKGROUND OF THE DISCLOSED TECHNOLOGY

After a layout design is derived from a circuit design, it is evaluated by a set of geometric constraints, or rules. This physical verification process is referred to as design rule checking (DRC). Design rule checking helps designers to achieve a high yield for the layout design during chip manufacturing. Another important physical verification process is called layout versus schematic (LVS). Layout versus schematic software translates the drawn shapes of the layout design into electrical components and connections between them. The result is an extracted circuit design in the form of a netlist. Layout versus schematic software then compares the extracted netlist with the original netlist to determine whether the layout design corresponds to the original schematic or circuit diagram of the circuit design, representing the circuit desired to be fabricated.

A full layout versus schematic checking process is an important and necessary signoff operation before the circuit design can be taped out. The process, however, can take a long time to finish as modern designs can contain billions of electronic components. Layout designers often want to perform physical verification frequently even before the layout design is completed. Sometimes, layout designers may also want to focus on verifying certain cells in the layout design. In both of these cases, the cells that are not completed or not intended to be checked need to be black boxed such that the layout versus schematic software will not spend time in extracting components and their connectivity inside them, determining their properties, performing comparison, and reporting errors which designers do not care about. In a conventional cell black boxing process, both the layout design and the foundry deck are needed for locating ports of the cells to be black boxed. The process is tedious, time-consuming and requires frequent human interventions.

### BRIEF SUMMARY OF THE DISCLOSED TECHNOLOGY

Various aspects of the present disclosed technology relate to techniques for layout versus schematic checking using automated cell black boxing. In one aspect, there is a method comprising: receiving a rule file of a chip manufacturer; determining text containers comprising information of cell ports based on statements for cell ports in the rule file; determining drawn layers comprising cell ports based on the text containers comprising information of cell ports if the rule file does not include statements for attaching text layers to layout design layers or based on statements for attaching each of the test containers comprising information of cell ports to a layout design layer in the rule file if the rule file includes statements for attaching text layers to layout design layers, the layout design layers comprising drawn layers; determining layout design layers connected to the drawn layers comprising cell ports based on statements for connecting two or more layout design layers in the rule file; generating a file for cell port detection which associates each of the text containers comprising information of cell ports with one or more of the drawn layers comprising cell ports and one or more of the layout design layers connected to the one or more of the drawn layers comprising cell ports; and storing the file for cell port detection.

The method may further comprise: extracting, from a layout design, cell ports for cells to be black boxed using the file for cell port detection. The method may still further comprise: extracting, from the layout design, connectivity based on the cell ports for cells to be black boxed; and comparing the extracted connectivity with corresponding connectivity in the circuit design. The extracting cell ports, the extracting connectivity, and the comparing may be operations in a layout versus schematic process, the method further comprising: modifying the layout design to fix errors found in the layout versus schematic process; and repeating the layout versus schematic process.

The determining drawn layers comprising cell ports may comprise: determining whether the one of the layout design layers is a drawn layer; and if not, determining the drawn layer comprising cell ports based on the one of the layout design layers.

The cells to be black boxed may be cells on levels below a top level in the circuit design or user-specified cells.

In another aspect, there is one or more computer-readable media storing computer-executable instructions for causing one or more processors to perform the above method.

In still another aspect, there is a system, comprising: one or more processors, the one or more processors programmed to perform the above method.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclosed technology. Thus, for example, those skilled in the art will recognize that the disclosed technology may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 illustrates an example of a computing system that may be used to implement various embodiments of the disclosed technology.

FIG. 2 illustrates an example of a multi-core processor unit that may be used to implement various embodiments of the disclosed technology.

FIG. 3 illustrates an example of a layout versus schematic tool that may be implemented according to various embodiments of the disclosed technology.

FIG. 4 illustrates a flowchart showing a process of automated cell black boxing that may be implemented according to various examples of the disclosed technology.

FIG. 5 illustrates an example of a layout design comprising hierarchical cells.

### DETAILED DESCRIPTION OF THE DISCLOSED TECHNOLOGY

### General Considerations

Various aspects of the present disclosed technology relate to techniques for layout versus schematic checking using automated cell black boxing. In the following description, numerous details are set forth for the purpose of explanation. However, one of ordinary skill in the art will realize that the disclosed technology may be practiced without the use of these specific details. In other instances, well-known features have not been described in detail to avoid obscuring the present disclosed technology.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. Moreover, for the sake of simplicity, the disclosed flow charts and block diagrams typically do not show the various ways in which particular methods can be used in conjunction with other methods. Additionally, the detailed description sometimes uses terms like “extract”, “determine”, and “generate” to describe the disclosed methods. Such terms are high-level abstractions of the actual operations that are performed. The actual operations that correspond to these terms will vary depending on the particular implementation and are readily discernible by one of ordinary skill in the art.

Also, as used herein, the term “design” is intended to encompass data describing an entire integrated circuit device. This term also is intended to encompass a smaller group of data describing one or more components of an entire device, however, such as a portion of an integrated circuit device. Still further, the term “design” also is intended to encompass data describing more than one micro device, such as data to be used to form multiple micro devices on a single wafer.

### Illustrative Operating Environment

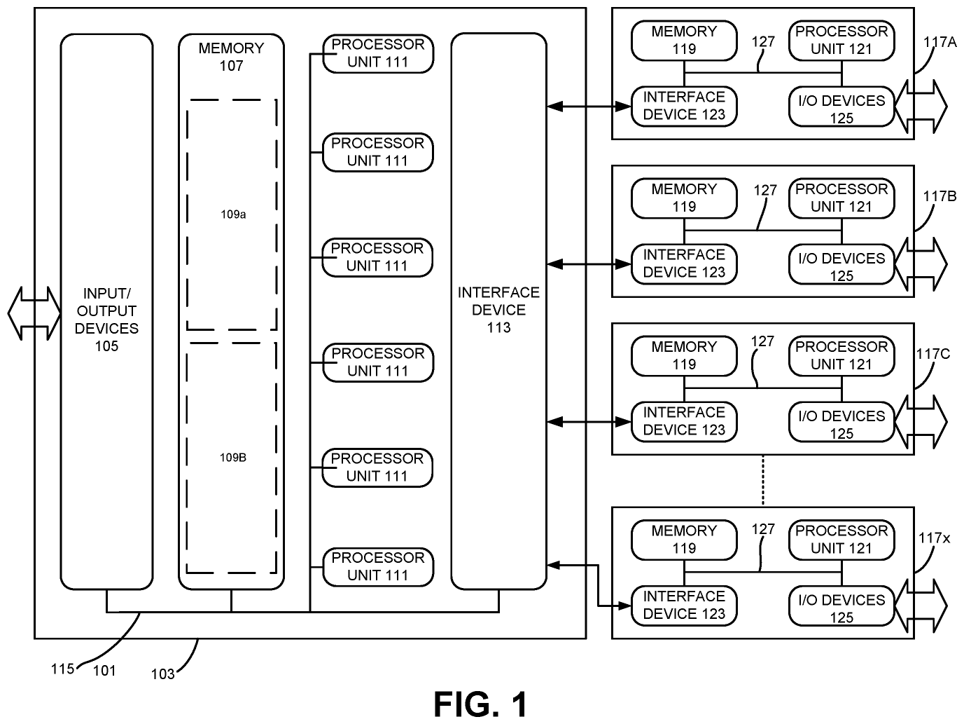

The execution of various electronic design automation processes according to embodiments of the disclosed technology may be implemented using computer-executable software instructions executed by one or more programmable computing devices. Because these embodiments of the disclosed technology may be implemented using software instructions, the components and operation of a generic programmable computer system on which various embodiments of the disclosed technology may be employed will first be described. Further, because of the complexity of some electronic design automation processes and the large size of many circuit designs, various electronic design automation tools are configured to operate on a computing system capable of simultaneously running multiple processing threads. The components and operation of a computer network having a host or master computer and one or more remote or servant computers therefore will be described with reference to FIG. 1. This operating environment is only one example of a suitable operating environment, however, and is not intended to suggest any limitation as to the scope of use or functionality of the disclosed technology.

In FIG. 1, the computer network 101 includes a master computer 103. In the illustrated example, the master computer 103 is a multi-processor computer that includes a plurality of input and output devices 105 and a memory 107. The input and output devices 105 may include any device for receiving input data from or providing output data to a user. The input devices may include, for example, a keyboard, microphone, scanner or pointing device for receiving input from a user. The output devices may then include a display monitor, speaker, printer or tactile feedback device. These devices and their connections are well known in the art, and thus will not be discussed at length here.

The memory 107 may similarly be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information.

As will be discussed in detail below, the master computer 103 runs a software application for performing one or more operations according to various examples of the disclosed technology. Accordingly, the memory 107 stores software instructions 109A that, when executed, will implement a software application for performing one or more operations. The memory 107 also stores data 109B to be used with the software application. In the illustrated embodiment, the data 109B contains process data that the software application uses to perform the operations, at least some of which may be parallel.

The master computer 103 also includes a plurality of processor units 111 and an interface device 113. The processor units 111 may be any type of processor device that can be programmed to execute the software instructions 109A, but will conventionally be a microprocessor device. For example, one or more of the processor units 111 may be a commercially generic programmable microprocessor, such as Intel® Pentium® or Xeon™ microprocessors, Advanced Micro Devices Athlon™ microprocessors or Motorola 68K/Coldfire® microprocessors. Alternately or additionally, one or more of the processor units 111 may be a custom-manufactured processor, such as a microprocessor designed to optimally perform specific types of mathematical operations. The interface device 113, the processor units 111, the memory 107 and the input/output devices 105 are connected together by a bus 115.

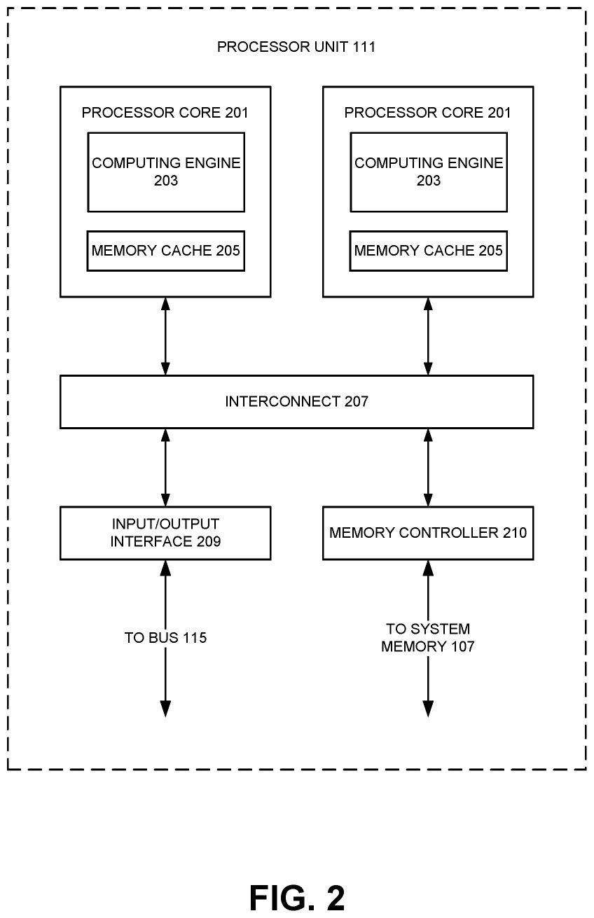

With some implementations of the disclosed technology, the master computing device 103 may employ one or more processing units 111 having more than one processor core. Accordingly, FIG. 2 illustrates an example of a multi-core processor unit 111 that may be employed with various embodiments of the disclosed technology. As seen in this figure, the processor unit 111 includes a plurality of processor cores 201. Each processor core 201 includes a computing engine 203 and a memory cache 205. As known to those of ordinary skill in the art, a computing engine contains logic devices for performing various computing functions, such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203 may then use its corresponding memory cache 205 to quickly store and retrieve data and/or instructions for execution.

Each processor core 201 is connected to an interconnect 207. The particular construction of the interconnect 207 may vary depending upon the architecture of the processor unit 111. With some processor cores 201, such as the Cell microprocessor created by Sony Corporation, Toshiba Corporation and IBM Corporation, the interconnect 207 may be implemented as an interconnect bus. With other processor units 111, however, such as the Opteron™ and Athlon™ dual-core processors available from Advanced Micro Devices of Sunnyvale, California, the interconnect 207 may be implemented as a system request interface device. In any case, the processor cores 201 communicate through the interconnect 207 with an input/output interface 209 and a memory controller 210. The input/output interface 209 provides a communication interface between the processor unit 111 and the bus 115. Similarly, the memory controller 210 controls the exchange of information between the processor unit 111 and the system memory 107. With some implementations of the disclosed technology, the processor units 111 may include additional components, such as a high-level cache memory accessible shared by the processor cores 201.

While FIG. 2 shows one illustration of a processor unit 111 that may be employed by some embodiments of the disclosed technology, it should be appreciated that this illustration is representative only, and is not intended to be limiting. Also, with some implementations, a multi-core processor unit 111 can be used in lieu of multiple, separate processor units 111. For example, rather than employing six separate processor units 111, an alternate implementation of the disclosed technology may employ a single processor unit 111 having six cores, two multi-core processor units each having three cores, a multi-core processor unit 111 with four cores together with two separate single-core processor units 111, etc.

Returning now to FIG. 1, the interface device 113 allows the master computer 103 to communicate with the servant computers 117A, 117B, 117C . . . 117x through a communication interface. The communication interface may be any suitable type of interface including, for example, a conventional wired network connection or an optically transmissive wired network connection. The communication interface may also be a wireless connection, such as a wireless optical connection, a radio frequency connection, an infrared connection, or even an acoustic connection. The interface device 113 translates data and control signals from the master computer 103 and each of the servant computers 117 into network messages according to one or more communication protocols, such as the transmission control protocol (TCP), the user datagram protocol (UDP), and the Internet protocol (IP). These and other conventional communication protocols are well known in the art, and thus will not be discussed here in more detail.

Each servant computer 117 may include a memory 119, a processor unit 121, an interface device 123, and, optionally, one more input/output devices 125 connected together by a system bus 127. As with the master computer 103, the optional input/output devices 125 for the servant computers 117 may include any conventional input or output devices, such as keyboards, pointing devices, microphones, display monitors, speakers, and printers. Similarly, the processor units 121 may be any type of conventional or custom-manufactured programmable processor device. For example, one or more of the processor units 121 may be commercially generic programmable microprocessors, such as Intel® Pentium® or Xeon™ microprocessors, Advanced Micro Devices Athlon™ microprocessors or Motorola 68K/Coldfire® microprocessors. Alternately, one or more of the processor units 121 may be custom-manufactured processors, such as microprocessors designed to optimally perform specific types of mathematical operations. Still further, one or more of the processor units 121 may have more than one core, as described with reference to FIG. 2 above. For example, with some implementations of the disclosed technology, one or more of the processor units 121 may be a Cell processor. The memory 119 then may be implemented using any combination of the computer readable media discussed above. Like the interface device 113, the interface devices 123 allow the servant computers 117 to communicate with the master computer 103 over the communication interface.

In the illustrated example, the master computer 103 is a multi-processor unit computer with multiple processor units 111, while each servant computer 117 has a single processor unit 121. It should be noted, however, that alternate implementations of the disclosed technology may employ a master computer having single processor unit 111. Further, one or more of the servant computers 117 may have multiple processor units 121, depending upon their intended use, as previously discussed. Also, while only a single interface device 113 or 123 is illustrated for both the master computer 103 and the servant computers, it should be noted that, with alternate embodiments of the disclosed technology, either the computer 103, one or more of the servant computers 117, or some combination of both may use two or more different interface devices 113 or 123 for communicating over multiple communication interfaces.

With various examples of the disclosed technology, the master computer 103 may be connected to one or more external data storage devices. These external data storage devices may be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information. According to some implementations of the disclosed technology, one or more of the servant computers 117 may alternately or additionally be connected to one or more external data storage devices. Typically, these external data storage devices will include data storage devices that also are connected to the master computer 103, but they also may be different from any data storage devices accessible by the master computer 103.

It also should be appreciated that the description of the computer network illustrated in FIG. 1 and FIG. 2 is provided as an example only, and it not intended to suggest any limitation as to the scope of use or functionality of alternate embodiments of the disclosed technology.

### Circuit Design Flow

Electronic circuits, such as integrated microcircuits, are used in a variety of products, from automobiles to microwaves to personal computers. Designing and fabricating integrated circuit devices typically involves many steps, sometimes referred to as a “design flow.” The particular steps of a design flow often are dependent upon the type of integrated circuit, its complexity, the design team, and the integrated circuit fabricator or foundry that will manufacture the microcircuit. Typically, software and hardware “tools” verify the design at various stages of the design flow by running software simulators and/or hardware emulators. These steps aid in the discovery of errors in the design, and allow the designers and engineers to correct or otherwise improve the design.

Several steps are common to most design flows. Initially, the specification for a new circuit is transformed into a logical design, sometimes referred to as a register transfer level (RTL) description of the circuit. With this logical design, the circuit is described in terms of both the exchange of signals between hardware registers and the logical operations that are performed on those signals. The logical design typically employs a Hardware Design Language (HDL), such as the Very high speed integrated circuit Hardware Design Language (VHDL). The logic of the circuit is then analyzed, to confirm that it will accurately perform the functions desired for the circuit. This analysis is sometimes referred to as “functional verification.”

After the accuracy of the logical design is confirmed, it is converted into a device design by synthesis software. The device design, which is typically in the form of a schematic or netlist, describes the specific electronic devices (such as transistors, resistors, and capacitors) that will be used in the circuit, along with their interconnections. This device design generally corresponds to the level of representation displayed in conventional circuit diagrams. The relationships between the electronic devices are then analyzed, to confirm that the circuit described by the device design will correctly perform the desired functions. This analysis is sometimes referred to as “formal verification.” Additionally, preliminary timing estimates for portions of the circuit are often made at this stage, using an assumed characteristic speed for each device, and incorporated into the verification process.

Once the components and their interconnections are established, the design is again transformed, this time into a physical design that describes specific geometric elements. This type of design often is referred to as a “layout” design. The geometric elements, which typically are polygons, define the shapes that will be created in various layers of material to manufacture the circuit. For digital circuits, automated place and route tools will be used to define the physical layouts, especially of wires that will be used to interconnect the circuit devices. Each layer of the microcircuit will have a corresponding layer representation in the layout design, and the geometric shapes described in a layer representation will define the relative locations of the circuit elements that will make up the circuit device. For example, shapes in the layer representation of a metal layer will define the locations of the metal wires used to connect the circuit devices. Custom layout editors allow a designer to custom design the layout, which is mainly used for analog, mixed-signal, RF, and standard-cell designs.

Integrated circuit layout descriptions can be provided in many different formats. The Graphic Data System II (GDSII) format is a popular format for transferring and archiving two-dimensional graphical IC layout data. Among other features, it contains a hierarchy of structures, each structure containing layout elements (e.g., polygons, paths or poly-lines, circles and textboxes). Other formats include an open source format named Open Access such as the Open Artwork System Interchange Standard (OASIS) proposed by Semiconductor Equipment and Materials International (SEMI). These various industry formats are used to define the geometrical information in IC layout designs that are employed to manufacture integrated circuits. Once the microcircuit device design is finalized, the layout portion of the design can be used by fabrication tools to manufacture the device using a photolithographic process.

Typically, a designer will perform a number of verification processes on the layout design. For example, the layout design may be analyzed to confirm that it complies with various design requirements, such as minimum spacings between geometric elements and minimum linewidths of geometric elements. In this process, a DRC (design rule checking) software tool takes as input a layout in the GDSII standard format and a list of rules specific to the semiconductor process chosen for fabrication. A set of rules for a particular process is referred to as a run-set, rule deck, or just a deck. An example of the format of a rule deck is the Standard Verification Rule Format (SVRF) by Mentor Graphics Corporation (now Siemens Industry Software Inc.).

The layout design are also analyzed to confirm that it accurately represents the circuit devices and their relationships described in the device design. A conventional LVS (layout versus schematic) process comprises two phases: extraction and comparison. In the extraction phase, a netlist is extracted from the layout design. The netlist includes not only types of and connectivity between the devices but also device parameters. In the comparison phase, the LVS tool compares the extracted netlist with the source netlist which is taken from the circuit schematic, and reports violations if any. LVS can be augmented by formal equivalence checking, which checks whether two circuits perform exactly the same function without demanding isomorphism.

Layout design data can include two different types of data: “drawn layer” design data and “derived layer” design data. The drawn layer data describes geometric features that will be used to form structures in layers of material to produce the integrated circuit. The drawn layer data will usually include polygons that will be used to form structures in metal layers, diffusion layers, and polysilicon layers. Thus, metal layers, diffusion layers, and polysilicon layers are drawn layers, drawing layer, or original layers. Derived layers include features made up of combinations of drawn layer data and other derived layer data. For example, with the transistor gate described above, the derived layer design data describing the gate will be derived from the intersection of a polygon in the polysilicon material layer and a polygon in the diffusion material layer.

The design of a new integrated circuit may include the interconnection of millions of transistors, resistors, capacitors, or other electrical structures into logic circuits, memory circuits, programmable field arrays, and other circuit devices. In order to allow a computer to more easily create and analyze these large data structures (and to allow human users to better understand these data structures), they are often hierarchically organized into smaller data structures, typically referred to as “cells.” For example, all of the transistors making up a memory circuit for storing a single bit may be categorized into a single “bit memory” cell. Rather than having to enumerate each transistor individually, the group of transistors making up a single-bit memory circuit can thus collectively be referred to and manipulated as a single unit. Similarly, the design data describing a larger 16-bit memory register circuit can be categorized into a single cell. This higher level “register cell” might then include sixteen bit memory cells, together with the design data describing other miscellaneous circuitry, such as an input/output circuit for transferring data into and out of each of the bit memory cells. Similarly, the design data describing a 128 kB memory array can then be concisely described as a combination of only 64,000 register cells, together with the design data describing its own miscellaneous circuitry, such as an input/output circuit for transferring data into and out of each of the register cells. Of course, while the above-described example is of design data organized hierarchically based upon circuit structures, circuit design data may alternately or additionally be organized hierarchically according to any desired criteria including, for example, a geographic grid of regular or arbitrary dimensions (e.g., windows), a memory amount available for performing operations on the design data, design element density, etc.

By categorizing microcircuit design data into hierarchical cells, large data structures can be processed more quickly and efficiently. For example, a circuit designer typically will analyze a design to ensure that each circuit feature described in the design complies with design rules specified by the foundry that will manufacture microcircuits from the design. With the above example, instead of having to analyze each feature in the entire 128 kB memory array, a design rule check process can analyze the features in a single bit cell. The results of the check will then be applicable to all of the single bit cells. Once it has confirmed that one instance of the single bit cells complies with the design rules, the design rule check process then can complete the analysis of a register cell simply by analyzing the features of its additional miscellaneous circuitry (which may itself be made of up one or more hierarchical cells). The results of this check will then be applicable to all of the register cells. Once it has confirmed that one instance of the register cells complies with the design rules, the design rule check software application can complete the analysis of the entire 128 KB memory array simply by analyzing the features of the additional miscellaneous circuitry in the memory array. Thus, the analysis of a large data structure can be compressed into the analyses of a relatively small number of cells making up the data structure.

### Layout Versus Schematic Tool

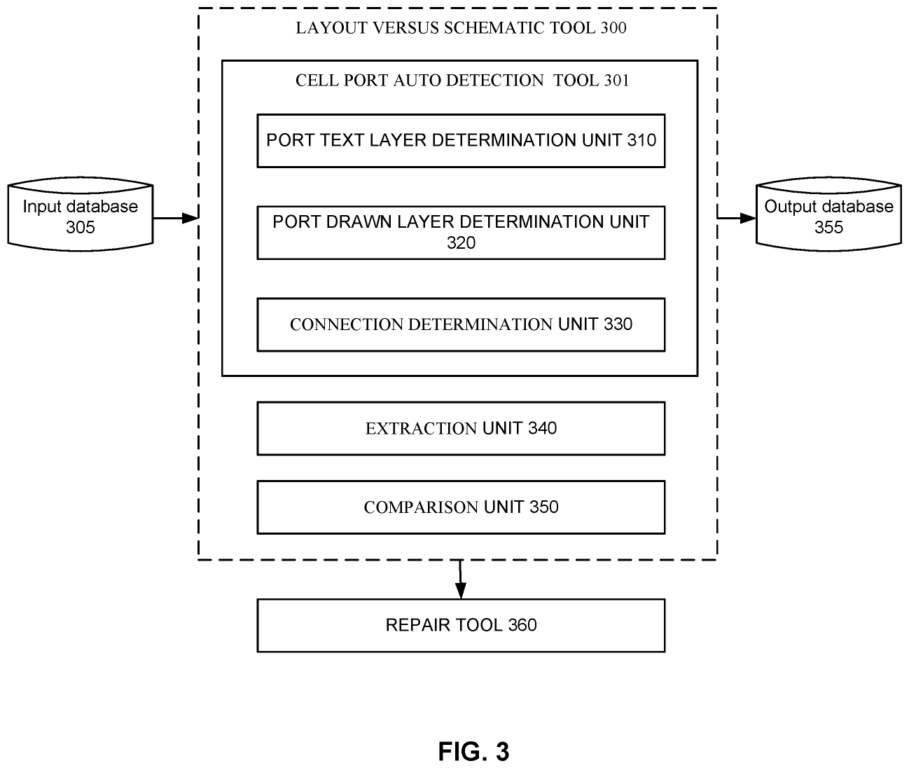

FIG. 3 illustrates an example of a layout versus schematic tool 300 that may be implemented according to various embodiments of the disclosed technology. As seen in this figure, the layout versus schematic tool 300 includes a cell port auto-detection tool 301, an extraction unit 340, and a comparison unit 350. The cell port auto-detection tool 301 includes a port text layer determination unit 310, a port drawn layer determination unit 320, and a connected layer determination unit 330. Various implementations of the layout versus schematic tool 300 may cooperate with (or incorporate) one or more of a repair tool 360, an input database 305 and an output database 355.

As will be discussed in more detail below, the layout versus schematic tool 300 can receive a circuit design, a layout design derived from the circuit design, and a rule file of a chip manufacturer from the input database 305. The cell port auto-detection tool 301 can use the rule file to generate a file for cell port detection. Specifically, the port text layer determination unit 310 can determine text containers comprising information of cell ports based on statements for cell ports in the rule file. The port drawn layer determination unit 320 can determine drawn layers comprising cell ports based on the text containers comprising information of cell ports if the rule file does not include statements for attaching text layers to layout design layers or based on statements for attaching each of the test containers comprising information of cell ports to a layout design layer in the rule file if the rule file includes statements for attaching text layers to layout design layers. The connected layer determination unit 330 can determine layout design layers connected to the drawn layers comprising cell ports based on statements for connecting two or more layout design layers in the rule file. The cell port auto-detection tool 301 can then generate the file for cell port detection by arranging each of the text containers comprising information of cell ports with one or more of the drawn layers comprising cell ports and one or more of the layout design layers connected to the one or more of the drawn layers comprising cell ports. Finally, the cell port auto-detection tool 301 can stores the file for cell port detection in the output database 355.

The extraction unit 340 can use the file for cell port detection to extract cell ports and their connectivity in the layout design. For the cells not to be black boxed, the extraction unit 340 can additionally extract devices inside the cells and their connectivity and cell properties/device parameters. The extraction unit 340 can then generate an extracted netlist. The comparison unit 350 can compare the extracted netlist with the original netlist and report any errors detected. The repair tool 360 can modify the layout design to fix the errors.

As previously noted, various examples of the disclosed technology may be implemented by one or more computing systems, such as the computing system illustrated in FIGS. 1 and 2. Accordingly, one or more of the port text layer determination unit 310, the port drawn layer determination unit 320, the connected layer determination unit 330, the extraction unit 340, the comparison unit 350, and the repair tool 360 may be implemented by executing programming instructions on one or more processors in one or more computing systems, such as the computing system illustrated in FIGS. 1 and 2. Correspondingly, some other embodiments of the disclosed technology may be implemented by software instructions, stored on a non-transitory computer-readable medium, for instructing one or more programmable computers/computer systems to perform the functions of one or more of the port text layer determination unit 310, the port drawn layer determination unit 320, the connected layer determination unit 330, the extraction unit 340, the comparison unit 350, and the repair tool 360. As used herein, the term “non-transitory computer-readable medium” refers to computer-readable medium that are capable of storing data for future retrieval, and not propagating electro-magnetic waves. The non-transitory computer-readable medium may be, for example, a magnetic storage device, an optical storage device, or a solid state storage device.

It also should be appreciated that, while the port text layer determination unit 310, the port drawn layer determination unit 320, the connected layer determination unit 330, the extraction unit 340, the comparison unit 350, and the repair tool 360 are shown as separate units in FIG. 3, a single computer (or a single processor within a master computer) or a single computer system may be used to implement some or all of these units at different times, or components of these units at different times.

With various examples of the disclosed technology, the input database 305 and the output database 355 may be implemented using any suitable computer readable storage device. That is, either of the input database 305 and the output database 355 may be implemented using any combination of computer readable storage devices including, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable storage devices may also include magnetic cassettes, magnetic tapes, magnetic disks or other magnetic storage devices, holographic storage devices, or any other non-transitory storage medium that can be used to store desired information. While the input database 305 and the output database 355 are shown as separate units in FIG. 3, a single data storage medium may be used to implement some or all of these databases.

### Process of Automated Cell Black Boxing

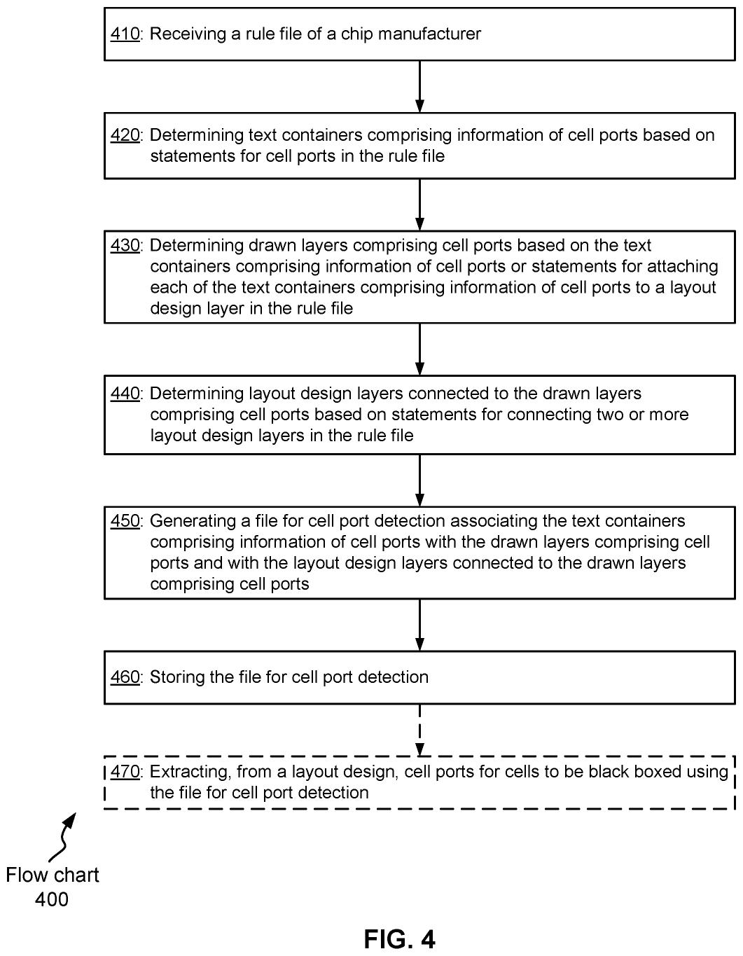

FIG. 4 illustrates a flowchart 400 showing an automated cell black boxing process that may be implemented according to various examples of the disclosed technology. For ease of understanding, methods of automated cell black boxing that may be employed according to various embodiments of the disclosed technology will be described with reference to the layout versus schematic tool 300 in FIG. 3 and the flow chart 400 illustrated in FIG. 4. It should be appreciated, however, that alternate implementations of a layout versus schematic tool may be used to perform the methods of automated cell black boxing illustrated by the flow chart 400 according to various embodiments of the disclosed technology. Likewise, the layout versus schematic tool 300 may be employed to perform other methods of automated cell black boxing according to various embodiments of the disclosed technology.

In operation 410 of the flow chart 400, the cell port auto-detection tool 301 receives a rule file of a chip manufacturer from the input database 305. The rule file may be referred to as a foundry deck as well. The rule file can include information related to layout design layers such as names, types of the layout design layers and connections between them. The layout design layers can comprise drawn layers. The layout design layers can further comprise derived layers. The rule file can also include abstract information about the cells such as layout design layers that include cell ports.

In operation 420, the port text layer determination unit 310 determines text containers comprising information of cell ports based on statements for cell ports in the rule file. A text container comprising information of cell ports can include names of cell ports. A text container can be in the form of a text layer or text included in a drawn layer. According to some embodiments of the disclosed technology, the port text layer determination unit 310 can first determine whether the rule file includes any statements that attach text layers to layout design layers. If there are such statements, the port text layer determination unit 310 can then identify all the text layers in the statements that attach text layers to layout design layers. In some rule files, a statement that attaches a text layer to a layout design layer starts with the word “ATTACH.” A text layer typically is the first layer after the word “ATTACH.” After identifying the text layers from these attach statements, the port text layer determination unit 310 can then check the statements for cell ports in the rule file to determine whether they contain any of these identified text layers. The text layers exiting in the statements for cell ports can be considered as the text containers comprising information of cell ports.

If the rule file does not have statements that attach text layers to layout design layers, the port text layer determination unit 310 can search for the statements for cell ports in the rule file and find the drawn layers in these statements. These drawn layers can be considered as the text containers comprising information of cell ports.

According to some other embodiments of the disclosed technology, the port text layer determination unit 310 can first search for the statements for cell ports in the rule file and determine whether these statements include any text layers. If these statements do not include any text layers, the port text layer determination unit 310 can treat drawn layers found in these statements as the text containers comprising information of cell ports. If the statements for cell ports include text layers, the port text layer determination unit 310 can treat these text layers as the text containers comprising information of cell ports. Then the port text layer determination unit 310 can search for statements that attach the identified text layers to layout design layers in the rule file. These layout design layers will be used in the next operation.

In operation 430, the port drawn layer determination unit 320 determines drawn layers comprising cell ports. If the rule file does not include statements for attaching text layers to layout design layers, the port drawn layer determination unit 320 can determine drawn layers comprising cell ports based on the text containers comprising information of cell ports because these text containers are the drawn layers comprising cell ports. If the rule file includes statements for attaching text layers to layout design layers, the port drawn layer determination unit 320 can determine drawn layers comprising cell ports based on the statements for attaching each of the test containers comprising information of cell ports to a layout design layer in the rule file. The port text layer determination unit 310 have already found these attach statements in the previous operation. The port drawn layer determination unit 320 can extract the layout design layers from the attach statements and determine whether they are drawn layers or not. If the extracted layout design layers are drawn layers, then they are the drawn layers comprising cell ports. If the extracted layout design layers are not drawn layers, the port drawn layer determination unit 320 can search for the drawn layers comprising cell ports based on the extracted layout design layers. With various implementations of the disclosed technology, the port drawn layer determination unit 320 can derive a derivation tree from an extracted layout design layer and select the first drawn layer out the derivation tree.

In operation 440, the connected layer determination unit 330 determines layout design layers connected to the drawn layers comprising cell ports based on statements for connecting two or more layout design layers in the rule file. The rule file may include statements starting with the word “CONNECT.” The statements typically have two layout design layers following the word “CONNECT.” The connected layer determination unit 330 can search for the connect statements that include the drawn layers comprising cell ports and found the layout design layers connected to the drawn layers comprising cell ports. Each of the drawn layers comprising cell ports may be connected to one or more layout design layers.

In operation 450, the cell port auto-detection tool 301 generates a file for cell port detection. The file for cell port detection associates each of the text containers comprising information of cell ports with one or more of the drawn layers comprising cell ports and one or more of the layout design layers connected to the one or more of the drawn layers comprising cell ports. The cell port auto-detection tool 301 can arrange the text containers comprising information of cell ports, the drawn layers comprising cell ports, and the layout design layers connected to the drawn layers comprising cell ports in a table with three columns for the three layers, respectively.

In operation 460, the cell port auto-detection tool 301 stores the file for cell port detection in the output database 355.

In operation 470, the extraction unit 340 extracts, from a layout design, cell ports for cells to be black boxed using the file for cell port detection. The layout design can be generated from a circuit design by using a place and route tool. The circuit design can be a full-chip design or a portion of a full-chip design. The circuit design can be described in the form of a netlist. The layout design can be in the GDSII standard format or the OASIS standard format. The cells to be black boxed can be cells on levels below a top level in the circuit design or user-specified cells.

The extraction unit 340 can extract, from the layout design, connectivity based on the cell ports for cells to be black boxed. For the cells not to be black boxed, the extraction unit 340 can extract devices inside the cells and their connectivity and cell properties/device parameters. The extraction unit 340 can then generate an extracted netlist. The comparison unit 350 can compare the extracted netlist with the original netlist and report any errors detected. The repair tool 360 can modify the layout design to fix the errors.

The above described black boxing process is fully automated, requiring essentially no human invention. The generation of the file for cell port detection is based on the rule file only. For a particular foundry process, the file for cell port detection can be generated just once. Different layout designs can use the same file for cell port detection for cell black boxing as long as these layout designs will use the same foundry process for chip manufacturing. By contrast, in a conventional cell black boxing process currently used in the industry, the cell port setup process typically needs the input of both the rule file and the layout design. For each of the cells to be black boxed, it checks the text and the drawn layers in the layout design, and then found the connection layers. It is performed on a cell-by-cell basis and for each layout design. Therefore, the whole process is tedious, time-consuming.

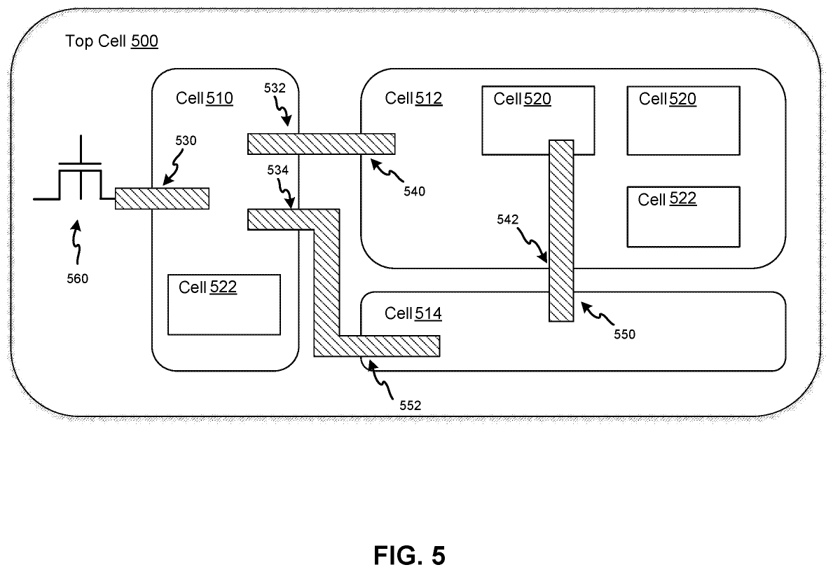

FIG. 5 illustrates an example of a layout design comprising hierarchical cells. The layout design comprises a top cell 500. The top cell 500 comprises cell 510, cell 512 and cell 514. The cell 510 comprises an instance of a cell 522. The cell 512 comprises two instances of cell 520 and one instance of cell 522. If the designer wants to only check the top level cells like the cell 500 in the layout design, the cells 510, 512 and 514 are to be black boxed. Using the file for cell port detection generated according to the various implementations of the disclosed technology, ports 530, 532 and 534 for the cell 510, ports 540 and 542 for the cell 512, and ports 550 and 552 for the cell 514 can be extracted. The connectivity between the cells 510, 512 and 514 and other devices such as a MOS transistor 560 can then be extracted. These devices within the cell 500 and the connectivity between them can be compared with the corresponding ones in the original schematic of the circuit design. The devices inside each of the black boxed cells and their properties and connectivity are not extracted and not compared. This avoids running a full sign-off LVS process.

According to various embodiments of the disclosed technology, a small portion of a layout design which a designer is interested in can be checked while other cells can be black boxed or totally ignored. Based on a list of cells provided by the designer, a new layout netlist can be extracted, a new source netlist can be derived from the original source netlist, and these two netlists are compared. This can allow designers to perform interactive and incremental LVS checks, skipping unnecessary extraction and comparison operations. This can also reduce irrelevant errors, making the debugging more focused and efficient. As a result, designers can identify and fix problems in the early stages and tape out the designs faster.

### Conclusion

While the disclosed technology has been described with respect to specific examples including presently preferred modes of carrying out the disclosed technology, those skilled in the art will appreciate that there are numerous variations and permutations of the above described systems and techniques that fall within the spirit and scope of the disclosed technology as set forth in the appended claims. For example, while specific terminology has been employed above to refer to electronic design automation processes, it should be appreciated that various examples of the disclosed technology may be implemented using any desired combination of electronic design automation processes.

1. A method, executed by at least one processor of a computer, comprising:
receiving a rule file of a chip manufacturer;
determining text containers comprising information of cell ports based on statements for cell ports in the rule file;
determining drawn layers comprising cell ports based on the text containers comprising information of cell ports if the rule file does not include statements for attaching text layers to layout design layers or based on statements for attaching each of the text containers comprising information of cell ports to a layout design layer in the rule file if the rule file includes statements for attaching text layers to layout design layers, the layout design layers comprising drawn layers;
determining layout design layers connected to the drawn layers comprising cell ports based on statements for connecting two or more layout design layers in the rule file;
generating a file for cell port detection which associates each of the text containers comprising information of cell ports with one or more of the drawn layers comprising cell ports and one or more of the layout design layers connected to the one or more of the drawn layers comprising cell ports; and
storing the file for cell port detection.

2. The method recited in claim 1, further comprising:
extracting, from a layout design, cell ports for cells to be black boxed using the file for cell port detection, wherein the layout design is derived from a circuit design.

3. The method recited in claim 2, further comprising:
extracting, from the layout design, connectivity based on the cell ports for cells to be black boxed; and
comparing the extracted connectivity with corresponding connectivity in the circuit design.

4. The method recited in claim 3, wherein the extracting cell ports, the extracting connectivity, and the comparing are operations in a layout versus schematic process, the method further comprising:
modifying the layout design to fix errors found in the layout versus schematic process; and
repeating the layout versus schematic process.

5. The method recited in claim 1, wherein the determining drawn layers comprising cell ports comprises:
determining whether the one of the layout design layers is a drawn layer; and
if not, determining the drawn layer comprising cell ports based on the one of the layout design layers.

6. The method recited in claim 1, wherein the cells to be black boxed are cells on levels below a top level in the circuit design or user-specified cells.

7. One or more non-transitory computer-readable media storing computer-executable instructions for causing one or more processors to perform a method, the method comprising:
receiving a rule file of a chip manufacturer;
determining text containers comprising information of cell ports based on statements for cell ports in the rule file;
determining drawn layers comprising cell ports based on the text containers comprising information of cell ports if the rule file does not include statements for attaching text layers to layout design layers or based on statements for attaching each of the text containers comprising information of cell ports to a layout design layer in the rule file if the rule file includes statements for attaching text layers to layout design layers, the layout design layers comprising drawn layers;
determining layout design layers connected to the drawn layers comprising cell ports based on statements for connecting two or more layout design layers in the rule file;
generating a file for cell port detection which associates each of the text containers comprising information of cell ports with one or more of the drawn layers comprising cell ports and one or more of the layout design layers connected to the one or more of the drawn layers comprising cell ports; and
storing the file for cell port detection.

8. The one or more non-transitory computer-readable media recited in claim 7, wherein the method further comprises:
extracting, from a layout design, cell ports for cells to be black boxed using the file for cell port detection, wherein the layout design is derived from a circuit design.

9. The one or more non-transitory computer-readable media recited in claim 8, wherein the method further comprises:
extracting, from the layout design, connectivity based on the cell ports for cells to be black boxed; and
comparing the extracted connectivity with corresponding connectivity in the circuit design.

10. The one or more non-transitory computer-readable media recited in claim 9, wherein the extracting cell ports, the extracting connectivity, and the comparing are operations in a layout versus schematic process, the method further comprising:
modifying the layout design to fix errors found in the layout versus schematic process; and
repeating the layout versus schematic process.

11. The one or more non-transitory computer-readable media recited in claim 7, wherein the determining drawn layers comprising cell ports comprises:
determining whether the one of the layout design layers is a drawn layer; and
if not, determining the drawn layer comprising cell ports based on the one of the layout design layers.

12. The one or more non-transitory computer-readable media recited in claim 7, wherein the cells to be black boxed are cells on levels below a top level in the circuit design or user-specified cells.

13. A system, comprising:
one or more processors, the one or more processors programmed to perform a method, the method comprising:
receiving a rule file of a chip manufacturer;
determining text containers comprising information of cell ports based on statements for cell ports in the rule file;
determining drawn layers comprising cell ports based on the text containers comprising information of cell ports if the rule file does not include statements for attaching text layers to layout design layers or based on statements for attaching each of the text containers comprising information of cell ports to a layout design layer in the rule file if the rule file includes statements for attaching text layers to layout design layers, the layout design layers comprising drawn layers;
determining layout design layers connected to the drawn layers comprising cell ports based on statements for connecting two or more layout design layers in the rule file;
generating a file for cell port detection which associates each of the text containers comprising information of cell ports with one or more of the drawn layers comprising cell ports and one or more of the layout design layers connected to the one or more of the drawn layers comprising cell ports; and
storing the file for cell port detection.

14. The system recited in claim 13, wherein the method further comprises:
extracting, from a layout design, cell ports for cells to be black boxed using the file for cell port detection, wherein the layout design is derived from a circuit design.

15. The system recited in claim 14, wherein the method further comprises:
extracting, from the layout design, connectivity based on the cell ports for cells to be black boxed; and
comparing the extracted connectivity with corresponding connectivity in the circuit design.

16. The system recited in claim 15, wherein the extracting cell ports, the extracting connectivity, and the comparing are operations in a layout versus schematic process, the method further comprising:
modifying the layout design to fix errors found in the layout versus schematic process; and
repeating the layout versus schematic process.

17. The system recited in claim 13, wherein the determining drawn layers comprising cell ports comprises:
determining whether the one of the layout design layers is a drawn layer; and
if not, determining the drawn layer comprising cell ports based on the one of the layout design layers.

18. The system recited in claim 13, wherein the cells to be black boxed are cells on levels below a top level in the circuit design or user-specified cells.
